(19) United States
(12) Patent Application Publication
(10) Pub. No.: US 2010/0078546 A1
(43) Pub. Date: Apr. 1, 2010

(54) OPTICAL MODULE AND OPTICAL SENSOR USING THE SAME AND METHOD FOR MANUFACTURING THEREOF

(76) Inventor: Chung Hie Kyoung, Gwangsan-GU (KR)

Correspondence Address: Philip R. Warn;Warn Partners P.C., P.O. BOX 70098, Rochester Hills, MI, 48307, US

(21) Appl. No.: 12/312,105

(22) PCT Filed: Oct. 19, 2007
(86) PCT No.: PCT/KR2007/005114

§ 371 Date: Apr. 24, 2009

(30) Foreign Application Priority Data
Oct. 24, 2006 (KR) 1020060103655
Jan. 16, 2007 (KR) 1020070004842

(51) Int. Cl. H01L 31/0232

(52) U.S. Cl. 250/225; 250/216; 250/237 G

(57) ABSTRACT

Provided are an optical module, an optical sensor using the optical module, and a method of manufacturing the optical module. The optical sensor includes: a semiconductor substrate having a plurality of optical paths; an optical glass substrate formed on the semiconductor substrate; a sample stage formed on the optical glass substrate; at least one sensor metal film formed on the sample stage, and sensing light by Surface Plasmon Resonance (SPR) to reflect the light at a pre-determined angle; a light source disposed on a lower surface of the semiconductor substrate, and emitting light having a specific wavelength toward one of the optical paths; a polarizing plate disposed between the semiconductor substrate and the light source, and polarizing the light emitted from the light source into transverse-magnetic light; a diffraction grating plate disposed between the semiconductor substrate and the optical glass substrate, and diffracting the polarized light at a specific angle to be incident on the sensor metal film; and at least one light receiver disposed on the lower surface of the semiconductor substrate, and detecting the light passed through at least one of the optical paths and reflected from the sensor metal film. According to the method, it is possible to manufacture an optical device having various functions.

### TECHNICAL FIELD

The present invention relates to an optical module, an optical sensor using the optical module, and a method of manufacturing the optical module, and more particularly, to a substrate-type optical module employing micro-optical technology using a planographic printing process, an optical sensor using the substrate-type optical module, and a method of manufacturing the substrate-type optical module.

### BACKGROUND ART

In general, micro-optical technology is used in various fields, such as displays, optical communication devices, and so on.

In particular, micro-optical technology having been used for manufacturing electronic devices is applied to manufacturing of micro-optical components. For example, micro-optical technology is used for manufacturing a microlens array and a color filter of a Charge-Coupled Device (CCD), a projection display, a Complementary Metal-Oxide Semiconductor (CMOS) Image Sensor (CIS), and so on. Also, micro-optical technology is used for manufacturing an optical module to be miniaturized, low priced, and have improved performance in various technical fields of optical components related to displays, such as a Back Light Unit (BLU) of a Liquid Crystal Display (LCD), etc., optical transceiver modules for communication, Planar Lightwave Circuits (PLCs) for communication, Red, Green and Blue (RGB) Light Emitting Diode (LED) optical modules, optical sensors, optical signal processors, optical Micro-Electro-Mechanical Systems (MEMSs), and so on.

First, conventional art of a substrate-type optical module, which is one aspect of the present invention, will be described below.

Currently, various kinds of material, such as optical glass, optical resin, silicon, etc., are being used for substrates of micro-optical devices, and surfaces of the substrates are processed by a planographic printing process, etching, molding, and so on. As an example of a transparent-substrate optical module manufactured by surface processing, there is a microlens array used in a CIS, a projection LCD, etc., and a BLU used in an LCD.

An image sensor and a projection LCD focus light using a microlens array in units of a pixel cell. This is for increasing intensity of light on a part of each pixel reacting to the light because transistors and electric wirings arranged in rectangular lattices occupy a considerable part of a substrate.

Light incident perpendicular to a microlens substrate is passed through each lens and centered on a focus of the lens. A CIS focuses light on a gate to enhance the photosensitivity of pixels, and a projection display increases the amount of light transmitted into a liquid crystal cell to enhance brightness.

In a conventional projection LCD, a microlens array is manufactured by the following process. A pattern of photoresist cells arranged at intervals of several tens of microns in a two-dimension form is formed by a planographic printing process. The pattern of photoresist cells is heated to melt photoresist, and thereby a spherical-shaped photoresist lens array is formed using surface tension of the melted photoresist. Finally, the spherical-shaped photoresist lens array is transferred on an optical thin film or optical substrate by dry etching.

Alternatively, a Boro-Phospho-Silicate Glass (BPSG) film melting at a low temperature of about several hundred degrees is formed on a substrate, and then the BPSG film is dry-etched using the photoresist cell pattern as an etch mask. After the photoresist pattern is removed, the resultant is heated to melt BPSG cells and form a spherical-shaped lens array using surface tension of the melted BPSG cells (see Japanese Laid-Open Patent Publication No. Heisei 06-326285, and Korean Laid-Open Patent No. 2005-0025230 and No. 2003-0004045).

A substrate, in which a microlens is formed, is attached to a liquid-crystal cell substrate, on which Thin Film Transistors (TFTs) are integrated, using optical resin so that optical paths are aligned with each other. According to microlens technology of projection LCDs, two substrates are attached to each other and used in this way, which may be a laminated-substrate-type optical module according to an object of the present invention.

In addition, LCD BLUs use a structure in which a sheet film, such as a prism, a diffusion plate, a polarizing plate, etc., is attached to a light guide plate made of transparent resin. In the structure, slim Cold Cathode Fluorescent Lamps (CCFLs) are aligned parallel with an edge on the border of the light guide plate. Light is incident to travel into the light guide plate while being totally reflected, and the light traveling while being totally reflected is refracted by a prism sheet attached to a substrate at the entire surface of the substrate in a direction perpendicular to the substrate and dispersed by the diffusion plate, thereby illuminating liquid-crystal cells in a direction perpendicular to the substrate.

This method uses the light guide plate to which various sheets are attached instead of stacking substrates according to the object of the present invention, but changes optical paths perpendicular to and parallel with the substrate to use them according to another object of the present invention. However, this may be a relatively simple function of equally dispersing light in a direction perpendicular to a substrate.

Besides a transparent substrate as described above, a silicon substrate may be used for a substrate-type optical module. In this case, a fine structure having a size of several to several hundred microns is fabricated using a pattern printed on a substrate surface by anisotropic etching, which is a wet-etching method using differences in etching characteristic of silicon crystal surfaces. Using such structures fabricated on a substrate, a photoelectric device, such as a light source, a photodetector, etc., or an individual optical device, such as an optical fiber, a lens, etc., is simply aligned and fixed by an individual device bonding method, such as flip-chip bonding, so that optical fabrication is finished.

This technology is referred to as Silicon Optical Bench (SiOB), which is used for packaging optical devices for communication. According to the technology, several optical components, such as a light source, a photodetector, an optical fiber, a microlens, etc., are formed on only one surface of a substrate, and an optical path is formed in a direction of a substrate surface without penetrating the substrate (see “ilica-based optical integrated circuits” IEE Proc. Optoelectronics, vol 143, 263-280, 1996).

The above-mentioned examples of a substrate-type micro-optical module are classified into the following types. In one example, optical components, such as a lens, etc., are fabricated on a surface of a transparent optical substrate to obtain a function of a lens array while passing light perpendicular to the substrate. Another example disperses and transmits light in a direction perpendicular to a substrate by an optical component fabricated on or attached to a substrate surface while making the light travel along the transparent substrate. The other example fabricates fine structures on a silicon substrate and optically aligns fine photoelectric devices using the fine structures.

Next, an optical sensor using a substrate-type optical module, particularly a Surface Plasmon Resonance (SPR) optical sensor that is another aspect of the present invention, will be described below. Thus far, substrate-optical modules have been used in the above-mentioned displays or in association with optical communication.

However, the present invention will apply a substrate-type optical module according to the one aspect to a bio-optical sensor. Needless to say, the object of the present invention can be applied to various fields, such as displays, optical communication devices, MEMs, and so on.

Such an SPR optical sensor manipulates an organic material at molecule level, and thus it is unnecessary to attach a fluorescent label. In addition, the SPR optical sensor can detect a very small amount of reaction occurring on a sensor surface at molecule level and thus is creating a lot of attention. Various methods for the SPR optical sensor, such as a method of using a prism (Biacore Inc.), a method of using a diffraction grating (HTS biosystems Inc.), a method of using an optical fiber or waveguide, etc., have already been developed (see “urface plasmon sensors review” Sensors and Actuators B54, 3-15, 1999).

A prism or diffraction grating-type SPR optical sensor fixes an incident angle of light incident on a sensor surface at a largest angle approximating an SPR angle at which a change in intensity of reflected light becomes greatest, and measures a sensing signal of the sensor according to change in intensity of reflected light induced by molecular binding on a surface (see U.S. Pat. No. 5965456). This method is frequently used due to high sensitivity of the sensor. However, this method uses a rotation device for adjusting the incident angle. Thus, the size of the sensor increases, and it is difficult to manufacture the sensor as a portable device or microchip.

A method for removing an incident-light rotation device and relatively miniaturizing a sensor has been developed by Texas Instruments (TI) Inc. The method uses light incident on a surface of a sensor, which is one surface of a polygonal prism, instead of parallel light as emitted light, and detects change in intensity of light emitted from a surface of the sensor according to change in angle using a detector array without a rotation device (EP No. 0797091). However, the method of TI using a detector array has low precision, and it is also difficult to manufacture the sensor as a micro-device.

Besides the above described method, there is another method using a diffraction grating and a micro-optical bench. According to this method, the volume of a sensor is large, and thus the sensor is hardly miniaturized and referred to as a substrate-type optical sensor module. In addition, since this method uses a fixed diffraction grating, it is impossible to adjust an SPR angle (see Korean Laid-Open Patent Publication No. 2001-0110428).

Three examples of substrate-type optical module technology are described above. First, substrate-type microlens array technology is merely for manufacturing fine lens cells using conventional semiconductor thin film technology or a planographic printing process, and also enables a very simple optical function.

Second, an LCD BLU has many functions such as light guide, reflection and refraction, diffusion, polarization, and so on. However, the LCD BLUE uses a light distribution or diffusion process changing line light emission with plane light emission rather than optical connection between specific positions. Thus, the LCD BLU has not yet come up to a level of precise micro-optical technology.

Third, the SiOB technology links optical functions of specific positions or devices together, which corresponds to real micro-optical technology. However, the SiOB technology uses a single surface of a single substrate and thus has a limited function or degree of integration.

### DISCLOSURE OF INVENTION TECHNICAL PROBLEM

The present invention is directed to connecting a plurality of optical components, such as a laser diode, a photodiode, a lens, a diffraction grating, a polarizing plate, etc., requiring optical alignment and integrating more optical functions to improve a structure of a substrate-type optical module, and thereby providing a substrate-type optical module that has various functions, which cannot be obtained from a conventional single-substrate-type optical module, and can be used for manufacturing various optical modules, such as an optical sensor, an optical communication device, a display, and so on.

The present invention is also directed to solving the above-described technical problems of a substrate-type optical module and providing an optical sensor, e.g., a Surface Plasmon Resonance (SPR) optical sensor, using a method of solving the problems. In particular, the present invention is directed to providing an enhanced SPR optical sensor that uses improved Silicon Optical Bench (SiOB) technology and is stacked with a transparent optical substrate to solve conventional problems of optical alignment, a size, a structure, a precision, and so on.

### TECHNICAL SOLUTION

A first aspect of the present invention provides an optical module comprising: a substrate having at least one optical path; and at least one lens inserted and fixed into the optical path to refract incident light.

Here, the optical path may be formed in the shape of a pyramidal hole perpendicularly penetrating the substrate so that an upper surface and a lower surface of the substrate can be optically connected.

The lens may have a spherical shape, and a part of the lens projected on the substrate may be evenly ground when the lens is inserted into the optical path.

The optical module may further comprise a light source for generating light on a substrate surface around the optical path or the evenly ground lens, or a photodetector for detecting incident light.

The light source may be a laser diode, and the photodetector may be a photodiode.

A second aspect of the present invention provides an optical module comprising: a substrate having at least one optical path having a transparent optical medium of a predetermined thickness; and an optical component formed on the transparent optical medium to perform an optical function.

Here, the transparent optical medium may comprise a silicon oxide glass film.

The optical path may be formed in the shape of a pyramidal groove on one surface or both surfaces of the substrate, and the transparent optical medium of a pre-determined thickness is formed on an inner surface of the groove so that an upper surface and a lower surface of the substrate can be optically connected.

The optical component may be one of a polarizing film, a phase film, a reflective film, a thin film filter, an optical coating film, and a transparent or diffraction pattern.

The substrate may comprise at least one of a semiconductor substrate, an optical glass substrate, a crystal substrate and an optical resin substrate, or a stack of the substrates.

The semiconductor substrate may be a silicon substrate having a [100] surface.

A third aspect of the present invention provides an optical sensor comprising: a semiconductor substrate having a plurality of optical paths; an optical glass substrate formed on the semiconductor substrate; a sample stage formed on the optical glass substrate; at least one sensor metal film formed on the sample stage, and sensing light by Surface Plasmon Resonance (SPR) to reflect the light at a predetermined angle; a light source disposed on a lower surface of the semiconductor substrate, and emitting light having a specific wavelength toward one of the optical paths; a polarizing plate disposed between the semiconductor substrate and the light source, and polarizing the light emitted from the light source into transverse-magnetic light; a diffraction grating plate disposed between the semiconductor substrate and the optical glass substrate, and diffracting the polarized light at a specific angle to be incident on the sensor metal film; and at least one light receiver disposed on the lower surface of the semiconductor substrate, and detecting the light passed through at least one of the optical paths and reflected from the sensor metal film.

Here, the light source may comprise a laser diode.

The diffraction grating plate may be installed to move along a guide groove formed on the semiconductor substrate in order to adjust the diffraction angle.

The optical sensor may further comprise an optical fluid for lubrication for making the diffraction grating plate smoothly move along the guide groove.

The light receiver may be a photodiode, and the light reflected from the sensor metal film may be reflected in the optical path and incident on the photodiode.

A fourth aspect of the present invention provides an optical sensor comprising: a semiconductor substrate having a plurality of optical paths; an optical glass substrate formed on the semiconductor substrate; a sample stage formed on the optical glass substrate; at least one sensor metal film formed on the sample stage, and sensing light by Surface Plasmon Resonance (SPR) to reflect the light at a predetermined angle; a light source disposed on a lower surface of the semiconductor substrate, and emitting light having a specific wavelength toward one of the optical paths; at least one lens inserted and fixed into the optical paths to refract the light emitted from the light source; a diffraction grating plate disposed between the semiconductor substrate and the optical glass substrate, and diffracting the light refracted by the lens at a specific angle to be incident on the sensor metal film; at least one light receiver disposed on the lower surface of the semiconductor substrate, and detecting the light passed through at least one of the optical paths and reflected from the sensor metal film; and a polarizing plate disposed between the semiconductor substrate and the light receiver, and polarizing the light reflected from the sensor metal film into transverse-magnetic light.

Here, the light receiver may be a photodiode having a form of a chip, and the light reflected from the sensor metal film may be refracted by the spherical-shaped light-receiving lens inserted into the optical path and incident on the photodiode.

A fifth aspect of the present invention provides an optical sensor comprising: a semiconductor substrate having at least one optical path; an optical glass substrate formed on the semiconductor substrate; a sample stage formed on the optical glass substrate; at least one sensor metal film formed on the sample stage, and sensing light by Surface Plasmon Resonance (SPR) to reflect the light at a predetermined angle; a light source disposed on a lower surface of the semiconductor substrate, and emitting light having a specific wavelength toward the optical path; at least one lens inserted and fixed into the optical path to refract the light emitted from the light source; a diffraction grating plate disposed between the semiconductor substrate and the optical glass substrate, and diffracting the light refracted by the lens at a specific angle to be incident on the sensor metal film; at least one light receiver disposed on a side of the semiconductor substrate, and detecting the light reflected from the sensor metal film and totally reflected by the optical glass substrate and the sample stage; and a polarizing plate disposed between the side of the semiconductor substrate and the light receiver, and polarizing the light reflected from the sensor metal film into transverse-magnetic light.

Here, the semiconductor substrate may be a silicon substrate, and the optical path may be formed in the shape of a pyramidal hole perpendicularly penetrating the silicon substrate so that an upper surface and the lower surface of the silicon substrate can be optically connected.

The sample stage may comprise an optical glass substrate or an optical resin substrate.

The light source may comprise a laser diode having a form of a chip.

The lens may have a spherical shape to convert the light emitted from the light source into parallel light, and a part of the lens projected on the substrate may be evenly ground when the lens is inserted into the optical path.

The diffraction grating plate may be installed to move between the semiconductor substrate and the optical glass substrate in order to adjust the diffraction angle.

The optical sensor may further comprise a protective glass of a predetermined thickness formed on a diffractive surface to prevent a diffraction grating of the diffraction grating plate from being optically contaminated.

The diffraction grating plate may prevent 0-th order diffraction and diffract light in symmetric directions for +I-th and −1-th order diffraction using a sectional structure of a diffraction grating line enhancing +−I-th order diffraction, and may be constituted to continuously or intermittently change a period of a grating.

The symmetrically disposed two light receivers may detect light reflected from the symmetrically disposed two sensor metal films, and signals of the two light receivers may be differentially amplified using light detected by one of the sensor metal films as reference light and light detected by the other sensor metal film as measurement light.

The light receiver may be a photodiode having a form of a chip, and the light reflected from the sensor metal film may be totally reflected by the optical glass substrate and the sample stage to be incident on the photodiode.

A sixth aspect of the present invention provides an optical sensor comprising: a semiconductor substrate; an optical glass substrate formed on the semiconductor substrate; a sample stage formed on the optical glass substrate; at least one sensor metal film formed on the sample stage, and sensing light by Surface Plasmon Resonance (SPR) to reflect the light at a predetermined angle; a light source disposed on the sample stage, and emitting light having a specific wavelength toward an upper surface of the semiconductor substrate; a plurality of diffraction gratings formed on the upper surface of the semiconductor substrate, and diffracting the light emitted from the light source at a specific angle to be incident on the sensor metal film; and at least one light receiver formed on the upper surface of the semiconductor substrate at a specific distance from the diffraction gratings, and detecting the light reflected from the sensor metal film.

Here, the semiconductor substrate may be a silicon substrate having a [100] surface, and two surfaces of a groove of the diffraction gratings may be formed by anisotropically etching silicon using a pattern of the diffraction gratings to have a [111] surface.

A cross-section of the diffraction grating groove may be an isosceles triangle, and the [111] grating surface and the [100] substrate surface may form an angle of 50 degrees to 60 degrees.

Diffraction of the diffraction gratings may be symmetric diffraction of +I-th order and −1-th order performed by twice reflecting the light emitted from the light source and perpendicularly incident on the substrate.

The light receiver may be a photodiode, and a grating pattern may be formed in the semiconductor substrate on the photodiode to reduce reflection of the light transmitted from the sensor metal film.

When the semiconductor substrate is a silicon substrate having a [100] surface, the grating pattern may be formed by anisotropically etching the silicon substrate to form an angle of 50 to 60 degrees between a grating surface and a substrate surface.

A seventh aspect of the present invention provides a method of manufacturing an optical module, comprising the steps of: (a) preparing a substrate having a predetermined thickness; (b) forming at least one optical path in the substrate; and (c) inserting and fixing at least one lens for refracting light incident into the optical path.

Here, when the substrate is a silicon substrate, the optical path may be formed in the shape of a pyramidal hole perpendicularly penetrating the silicon substrate by anisotropically etching the silicon substrate using a specific pattern.

When the substrate is a silicon substrate having a [100] surface, step (b) may comprise the steps of: (b-1) forming a silicon nitride film or a silicon oxide film on at least one of an upper surface and a lower surface of the silicon substrate; (b-2) forming a rectangular photosensitive film pattern on the silicon nitride film or silicon oxide film using a planographic printing process; (b-3) transfer-etching the photosensitive film pattern to transfer the pattern on the silicon nitride film or silicon oxide film; and (b-4) anisotropically etching the silicon substrate using the pattern transferred on the silicon nitride film or silicon oxide film as an etch mask to form the optical path having a pyramidal hole.

The lens may have a spherical shape, and a part of the lens projected on the substrate may be evenly ground when the lens is inserted into the optical path.

A light source for generating light through flip-chip bonding or a photodetector for detecting incident light may be attached on a substrate surface around the optical path or the evenly ground lens.

An eighth aspect of the present invention provides a method of manufacturing an optical module, comprising the steps of: (a<1>) preparing a substrate having a predetermined thickness; (b<1>) forming at least one optical path having a transparent optical medium on the substrate; and (c<1>) forming an optical component for performing various optical functions on the transparent optical medium.

Here, when the substrate is a silicon substrate having a [100] surface, the transparent optical medium may be formed by oxidizing a part of the silicon substrate.

When the substrate is a silicon substrate, step (b<1>) may comprise the steps of: (b'-I) forming an optical path pattern on at least one of an upper surface and a lower surface of the silicon substrate using a planographic printing process; and (b'-2) anisotropically etching the silicon substrate to leave a silicon film having a predetermined thickness, and then oxidizing the silicon film to convert the silicon film into a transparent optical medium having a silicon oxide glass film and thereby form the optical path.

Step (b'-2) may comprise depositing Boro-Phospho-Silicate Glass (BPSG) using Chemical Vapor Deposition (CVD) or Flame Hydrolysis Deposition (FHD) and melting the deposited BPSG when a surface of the silicon oxide glass film is too rough to be optically used.

Step (c<1>) may comprise attaching a polarizing plate film or a phase plate film on the transparent optical medium.

Step (c<1>) may comprise coating a reflective film or a multilayer optical thin film on the transparent optical medium.

Step (c<1>) may comprise forming a transparent pattern or a diffraction pattern on the transparent optical medium.

### ADVANTAGEOUS EFFECTS

According to the inventive optical module, optical sensor using the optical module, and method of manufacturing the optical module, an optical path penetrating a silicon substrate is formed by anisotropically etching the silicon substrate to optically connect upper and lower surfaces of the silicon substrate, and thus the upper and lower surfaces can be used as one optical system.

In addition, it is possible to optically align optical components parallel and perpendicular to a substrate using structures precisely formed by anisotropic etching in an optical path or on an upper or lower surface of the substrate.

Furthermore, a silicon substrate and a transparent optical material substrate are manufactured by a planographic printing process, and aligned and stacked to be bonded together. Thus, it is possible to efficiently mass-produce a small micro-optical module that performs a high-level function, comprises a plurality of optical components, and is easily aligned.

### BRIEF DESCRIPTION OF THE DRAWINGS

FIG. 1 illustrates structures of various unit devices constituting a substrate-type optical module according to the present invention;

FIG. 2 is a plan view and a cross-section view of an optical sensor using a laminated optical module according to a first exemplary embodiment of the present invention;

FIG. 3 is a plan view and a cross-section view of an optical sensor using a laminated optical module according to a second exemplary embodiment of the present invention;

FIG. 4 is a plan view and a cross-section view of an optical sensor using a laminated optical module according to a third exemplary embodiment of the present invention; and

FIG. 5 is a plan view and a cross-section view of an optical sensor using a laminated optical module according to a fourth exemplary embodiment of the present invention.

### MODE FOR THE INVENTION

Hereinafter, exemplary embodiments of the present invention will be described in detail. However, the present invention is not limited to the embodiments disclosed below, but can be implemented in various forms. Therefore, the following embodiments are described in order for this disclosure to be complete and enabling to those of ordinary skill in the art.

First, the present invention relates to a substrate-type optical module manufactured by a planographic printing process and an optical sensor module using the substrate-type optical module.

An optical material, such as optical glass, is stacked on a silicon substrate to be used as a substrate of the optical module according to an exemplary embodiment of the present invention. The optical module is manufactured by forming optical components, such as a lens, a diffraction grating, a thin film filter, etc., in or on the silicon substrate to unite the optical components with the substrate.

An optical path perpendicularly penetrating the silicon substrate is formed using an anisotropic etching method. A ball lens is inserted and fixed into the optical path, and a part of the ball lens projected on the substrate is ground. And then, semiconductor optoelectronic devices, such as a light source and a photodetector, are bonded to the optical path by flip-chip bonding. Thus, the optical path performs a lens function together with a light receiving function or a light emitting function. A structure of an optical module substrate including the optical path, and a method of manufacturing the optical module will be described below.

The above-mentioned optical module substrates may be stacked in sequence, and various optical components, such as a diffraction optical plate, a polarizing plate, etc., may be disposed on or between the substrates. When a structure of an optical module is constituted so that the optical components can move along a substrate surface, it is possible to manufacture an optical device having various functions.

A structure of a Surface Plasmon Resonance (SPR) optical sensor module will be described, in which a guide groove is formed on the above mentioned optical module substrate to enable a diffraction grating plate to move along the guide groove in the substrate surface so that a diffraction angle of light passed through an optical path and the diffraction grating plate can be adjusted according to movement of the diffraction grating plate.

In such an SPR optical sensor module, a semiconductor laser and a photodiode are bonded to a substrate surface by flip-chip bonding, and thereby all optical systems may be included in a stacked structure of a silicon substrate and an optical glass substrate.

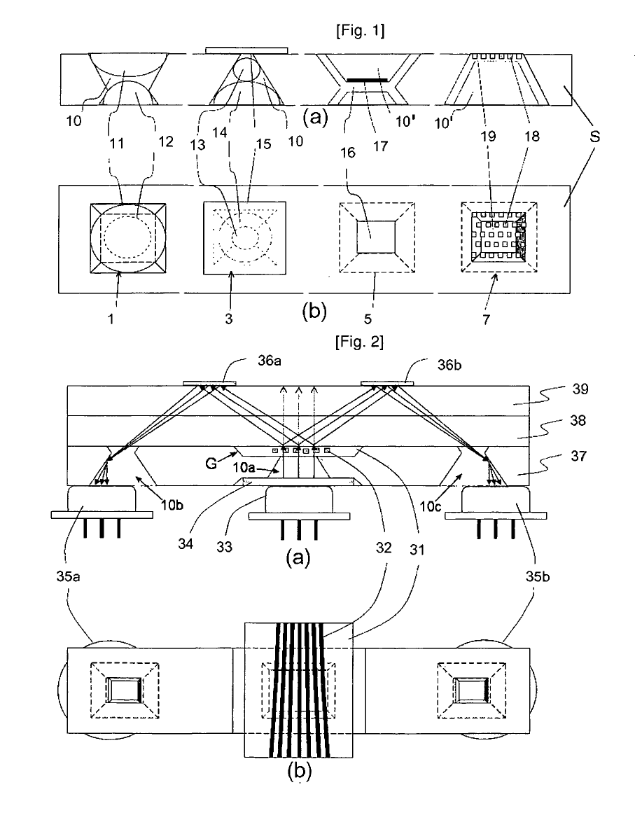

FIG. 1 illustrates structures of various unit devices constituting a substrate-type optical module according to the present invention. FIG. 1 (A) shows cross-section views, and FIG. 1 (B) shows plan views.

Referring to FIG. 1, a substrate-type optical module according to the present invention comprises a substrate S having at least one optical path 1 and 3, and at least one lens 11, 12, 13 and 14 inserted and fixed into the optical paths 1 and 3 to refract incident light.

Here, the optical paths 1 and 3 comprise, for example, a pyramidal hole 10 perpendicularly penetrating the substrate so that an upper surface and a lower surface of the substrate S can be optically connected.

The substrate S may be at least one of a semiconductor substrate, e.g., a silicon substrate, an optical glass substrate, a crystal substrate, such as a sapphire substrate, etc., and an optical resin substrate, or a stacked combination of the substrates. For example, the substrate S may comprise at least one silicon substrate or stacked substrates including at least one silicon substrate.

Here, the semiconductor substrate may be, for example, a silicon substrate. There is no limit to a thickness of the silicon substrate, but the thickness may generally range from 0.1 mm to 5 mm. As a substrate surface, a [100], [110], [111] or [211] surface may be used, but a [100] surface that is most frequently used as a silicon substrate may be generally used.

The lenses 11, 12, 13 and 14 may be implemented by, for example, ball lenses. When the lenses 11, 12, 13 and 14 are inserted into the optical paths 1 and 3, a part of the lenses 11, 12, 13 and 14 projected on the substrate S is evenly ground, and a space may be filled with, for example, an optical epoxy, and so on.

Additionally, an optoelectronic device 15, such as a light source, e.g., a laser diode, for generating light, or a photodetector, e.g., a photodiode, for detecting incident light, etc., may be bonded around the optical paths 1 and 3, that is, on the substrate surface of the gateway or the evenly ground lens of the gateway.

A method of manufacturing a substrate-type optical module according to an exemplary embodiment of the present invention will be described in detail below.

First, the substrate S, e.g., a silicon substrate, having a predetermined thickness, which may be about 0.1 mm to 5 mm, is prepared, and then the silicon substrate S is anisotropically etched using a specific pattern to form the optical paths 1 and 3 having, for example, the pyramidal hole 10 perpendicularly penetrating the substrate.

Subsequently, at least one lens 11, 12, 13 and 14 for refracting incident light is inserted and fixed into the optical paths 1 and 3.

Here, the lenses 11, 12, 13 and 14 may be implemented by, for example, ball lenses. When the ball lenses are inserted into the optical paths 1 and 3, a part of the ball lenses projected on the substrate S may be evenly ground, and a space may be filled with, for example, an optical epoxy.

Additionally, the optoelectronic device 15, such as a light source, e.g., a laser diode, for generating light, or a photodetector, e.g., a photodiode, for detecting incident light, etc., may be easily bonded around the optical paths 1 and 3, that is, on the substrate surface of the gateway or the evenly ground lens of the gateway by a device chip bonding method, e.g., flip-chip bonding.

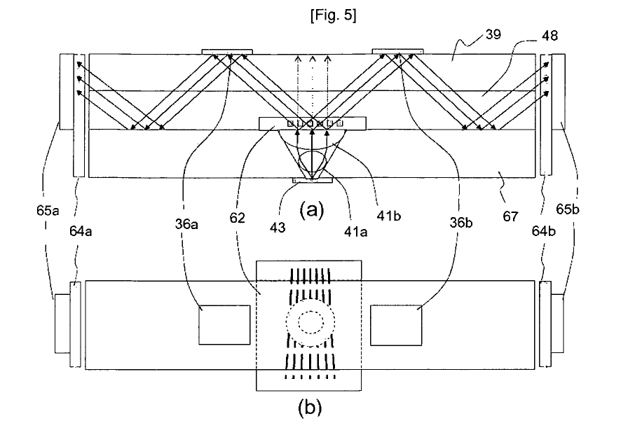

In this case, a device emitting light from its surface or receiving light at the surface is suited to the optoelectronic device 15. In particular, when a Surface Emitting Laser (SEL) is used as a laser diode, i.e., a light source, it is easy to transmit light to the optical paths 1 and 3 because light is emitted from the surface of the device chip. In addition, when a silicon substrate is used, a photodetector, i.e., light receivers 55a and 55b in FIG. 4, may be fabricated directly on the substrate.

Meanwhile, a case in which the optical paths 1 and 3 are formed in a rectangular pattern using a silicon substrate having a [100] surface will be described.

A process of forming a rectangular optical path by removing silicon from a [100] substrate surface is as follows. First, a silicon nitride film or a silicon oxide film is formed on at least one of an upper surface and a lower surface of the silicon substrate having a [100] surface.

After a rectangular Photoresist (PR) pattern is formed by a planographic printing process so that an edge of the PR pattern is parallel to the [110] surface, the PR pattern is transfer-etched to transfer the PR pattern on the silicon nitride film or the silicon oxide film under the PR pattern.

Subsequently, the silicon substrate under the silicon nitride film or the silicon oxide film is anisotropically etched using the transferred pattern on the silicon nitride film or silicon oxide film as an etch mask to form the optical paths 1 and 3 having the pyramidal hole 10.

A structure of a substrate-type optical module and a method of manufacturing the optical module according to another exemplary embodiment of the present invention will be described in detail below.

As illustrated in FIG. 1, a substrate-type optical module according to another example of the present invention comprises a substrate S in which at least one optical path 5 and 7 having transparent optical media 16 and 19 of a predetermined thickness is formed, and optical components 17 and 18 formed on the transparent optical media 16 and 19 to perform various optical functions.

Here, the transparent optical media 16 and 19 may comprise a silicon oxide glass film.

The optical paths 5 and 7 comprise a pyramidal groove 10 formed in one surface or both surfaces of the surface S and the transparent optical media 16 and 19 having a predetermined thickness, which may be 50 D or less, so that an upper surface and a lower surface of the substrate S′ can be optically connected via an inner surface of the groove 10′.

The optical components 17 and 18 each may be one of, for example, a polarizing film, a phase film, a reflective film, a thin film filter, an optical coating film, and a transparent or diffraction pattern.

A method of manufacturing a substrate-type optical module according to another exemplary embodiment of the present invention will be described in detail below.

First, the substrate S, e.g., a silicon substrate, having a predetermined thickness, which may be about 0.1 mm to 5 mm, is prepared, and then at least one optical path 5 and 7 having the transparent optical media 16 and 19 is formed in the substrate.

Here, when the substrate S is a silicon substrate having a [100] surface, the transparent optical media 16 and 19 are formed by oxidizing a part of the silicon substrate.

More particularly, an optical path pattern is formed on at least one of an upper surface and a lower surface of the silicon substrate by, for example, a planographic printing process, the silicon substrate is anisotropically etched to leave a silicon film having a predetermined thickness (generally about 50 D or less), the silicon film is oxidized, and thereby the optical media 16 and 19 are formed.

When a surface of the silicon oxide glass film is too rough to be optically used, Boro-Phospho-Silicate Glass (BPSG) may be deposited using Chemical Vapor Deposition (CVD), Flame Hydrolysis Deposition (FHD), etc., and the deposited BPSG may be melted to enhance the surface for optical use.

Finally, the optical components 17 and 18 for performing various optical functions are formed on the transparent optical media 16 and 19.

In other words, to perform desired optical functions in the optical paths 5 and 7, the optical functions are added using the transparent optical media 16 and 19, i.e., the silicon oxide glass film, of the optical paths 5 and 7.

More specifically, through, for example, a planographic printing process, a thickness, a transparency, etc., of a thin film may be patternized, or a diffraction component, etc., may be engraved. In addition, a uniform optical coating film or an optical coating film patterned by a planographic printing process may be added.

As described above, a silicon film having a predetermined thickness is left in a process of anisotropically etching a silicon substrate and then is oxidized, thereby forming an optical path having a silicon oxide glass film that is a transparent optical medium having a predetermined thickness.

The optical path including such a silicon oxide glass film is useful because it is possible to attach a polarizing plate or a phase plate film, coat the reflective film or multilayer optical thin film 17, or form the transparent pattern or diffraction pattern 18 on the oxide silicon glass film.

As described above, when a wavelength of light passed through the optical paths 1 and 3 is shorter than that of a silicon band gap, silicon absorbing light is removed from the optical paths 1 and 3, or a silicon substrate is anisotropically etched to leave a part of a thickness of silicon and then is oxidized to be converted into the transparent optical media 16 and 19, thereby forming the optical paths 5 and 7.

Meanwhile, a silicon substrate itself is a transparent media in a wavelength band in which a wavelength of light passed through an optical path is longer than that of a band gap wavelength, and thus the silicon optical paths 1, 3, 5 and 7 of the present invention are not necessary. However, an optical function, such as the lenses 11, 12, 13 and 14, diffraction, reflection, absorption, etc., may be performed in the optical paths 1, 3, 5 and 7 using a physical structure formed by anisotropic etching, which is included in the scope of the present invention.

According to another aspect of the present invention, to solve a problem of a conventional SPR optical sensor, an optical bench of a silicon substrate using an optical module according to the above described aspect of the present invention and an optical bench of an optical glass substrate having a metal sensor film are stacked to constitute an SPR optical sensor (see FIGS. 2 to 5). A constitution of the SPR optical sensor is specified below according to functions.

1. Light source: having a laser diode. According to a constitution of an optical system, the light source may include an optical path of the silicon substrate having optical components applied to one aspect of the present invention.

2. Optical component on a substrate surface (diffraction grating plate and polarizing plate): disposed between the silicon substrate and the optical glass substrate. The diffraction grating plate serves to transmit light emitted from the light source to a sensor part at a specific angle, and the polarizing plate selects a polarization state to sense only Transverse Magnetic (TM) light of a sensor signal.

3. Plasmon sensor: formed by coating a metal film of gold, silver, etc., having a thickness of several tens of nanometers on the optical glass substrate. A material to be sensed, e.g., protein, DNA and cell, is physically and chemically fixed on the metal film.

4. Light receiver: having a photodiode and a condensing optical system. The condensing optical system varies according to a position of the photodiode, and exemplary embodiments of the present invention described below suggest various constitutions.

### FIRST EXEMPLARY EMBODIMENT

FIG. 2 is a plan view and a cross-section view of an optical sensor using a laminated optical module according to a first exemplary embodiment of the present invention. FIG. 2 (A) is a cross-section view of an entire SPR optical sensor according to the first exemplary embodiment of the present invention, and FIG. 2 (B) is a plan view of a silicon substrate of the SPR optical sensor according to the first exemplary embodiment of the present invention.

Referring to FIG. 2, an optical sensor using a laminated optical module comprises a semiconductor substrate 37, an optical glass substrate 38, a sample stage 39, sensor metal films 36a and 36b, a light source 33, a polarizing plate 34, a diffraction grating plate 31, and light receivers 35a and 35b.

Here, the semiconductor substrate may be implemented by, for example, a silicon substrate. As described above, a plurality of optical paths 10a, 10b and 10c having, for example, a pyramidal hole are formed to perpendicularly penetrate the substrate so that an upper surface and a lower surface of the semiconductor substrate 37 are optically connected.

The optical glass substrate 38 is formed and stacked on the semiconductor substrate 37, and leaves a suitable space between the semiconductor substrate 37 and the sensor metal films 36a and 36b to maintain an appropriate incident angle.

The sample stage 39 is formed and stacked on the optical glass substrate 38, and serves to support the sensor metal films 36a and 36b coated by a sensor material, e.g., an antibody, exciting a surface plasmon. In addition, the sample stage 39 serves to constitute a path of a sample fluid, e.g., a solution containing an antibody, containing a material to be examined, e.g., an antibody, combined with the sensor material on the sensor metal films 36a and 36b.

The functions need to be changed according to an object to be examined, and are frequently changed due to contamination. Therefore, another optical glass substrate or optical resin substrate is frequently used (referred to as “sample stage” to distinguish this from the optical glass substrate stacked on the semiconductor substrate).

At least one of the sensor metal films 36a and 36b is disposed on the sample stage 39, and performs a function of sensing light by SPR and reflecting the light at a predetermined angle. In general, the sensor metal films 36a and 36b and the sample stage 39 are inclusively referred to as a plasmon sensor.

The light source 33 comprises, for example, a laser diode. The light source 33 is disposed on the lower surface of the semiconductor substrate 37, and functions to emit light having a specific wavelength toward the optical path 10a.

The polarizing plate 34 is disposed between the semiconductor substrate 37 and the light source 33, and functions to polarize light emitted from the light source 33 into TM light. The polarizing plate 34 may be disposed anywhere between the light source 33 and the light receivers 35a and 35b.

The diffraction grating plate 31 is disposed between the semiconductor substrate 37 and the optical glass substrate 38, and functions to diffract light polarized by the polarizing plate 34 at a specific angle and transmit the light to the sensor metal films 36a and 36b.

The diffraction grating plate 31 may be installed to move along a guide groove G formed on the semiconductor substrate 37 in order to adjust the diffraction angle, but is not limited thereto. The diffraction grating plate 31 may be fixed on the semiconductor substrate 37, or fixed and coupled to an optical path.

Since an optical fluid for lubrication may be used for making the diffraction grating plate 31 smoothly move along the guide groove G, a thin protective glass needs to be fixed on a diffractive surface to prevent a diffraction grating 32 of the diffraction grating plate 31 from being optically contaminated.

As the protective glass, an optical glass having a thickness of about 0.1 mm to 0.2 mm may be fixed, and the circumference of the diffraction grating plate 31 may be sealed airtight by, for example, an optical epoxy, etc. Alternatively, the optical glass may be heated to be melted and fixed. The melting and fixing requires a temperature of about 1000 <0>C, according to the quality of glass.

In addition, the diffraction grating plate 31 may prevent 0-th order diffraction and diffract light in symmetric directions for +I-th and −1-th order diffraction using a sectional structure of a diffraction grating line enhancing +−I-th order diffraction. The diffraction grating plate 31 may be constituted so that a period of the diffraction grating 32 can continuously or intermittently change.

Here, symmetric diffraction of the diffraction grating plate 31 may be used for doubling a sensor channel or improving sensitivity of the optical sensor. Light reflected from the two symmetrically disposed sensor metal films 36a and 36b is detected by the two symmetrically disposed light receivers 35a and 35b, and signals of the two light receivers 35a and 35b are differentially amplified using light detected by one of the light receivers 36a and 36b as reference light and light detected by the other one of the light receivers 36a and 36b as measurement light, thereby improving sensitivity of the optical sensor.

The light receivers 35a and 35b comprise, for example, a photodiode. The light receivers 35a and 35b are symmetrically disposed with respect to the light source 33 on the lower surface of the semiconductor substrate 37, and function to detect light passed through the optical paths 10b and 10c and reflected from the sensor metal films 36a and 36b.

Here, the light reflected from the sensor metal films 36a and 36b may be reflected in the optical paths 10b and 10c and incident on the light receivers 35a and 35b.

In the first exemplary embodiment of the present invention, a can-shaped module, such as the light source 33 or the photodetectors, i.e., the light receivers 35a and 35b, is used. Since the module generally includes a lens therein, it is unnecessary to use a lens in the optical paths 10b and 10c. In this case, the optical paths 10b and 10c merely provide an optical path s function of allowing the semiconductor to be used at the both surfaces.

In general, light collimated into parallel light by a microlens is transmitted to the sensor metal films 36a and 36b, but converged light or diverged light may be used according to a constitution of an optical system.

Operation of the optical sensor using a laminated optical module according to the first exemplary embodiment of the present invention will be described in detail below.

First, light emitted from the light source 33 attached on the lower surface of the semiconductor substrate 37 passes through the polarizing plate 34 and the optical path 10a, is diffracted by the diffraction grating plate 31 disposed on the upper surface of the semiconductor substrate 37, and travels toward the sensor metal films 36a and 36b disposed on the sample stage 39.

Here, an incident angle of the light must be set to an incident angle of a highest sensitivity approximating an SPR angle of the sensor metal films 36a and 36b.

Subsequently, light reflected from the sensor metal films 36a and 36b passes through the optical paths 10b and 10c formed in the semiconductor substrate 37 and is detected by the light receivers 35a and 35b disposed on the lower surface of the semiconductor substrate 37. Here, the light traveling from the sample stage 39 is reflected in the optical paths 10b and 10c and incident on the light receivers 35a and 35b.

### SECOND EXEMPLARY EMBODIMENT

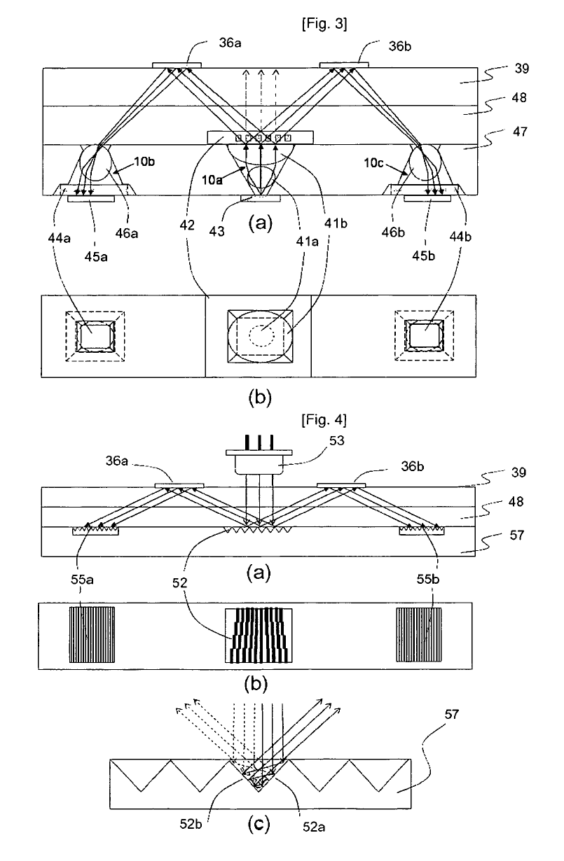

FIG. 3 is a plan view and a cross-section view of an optical sensor using a laminated optical module according to a second exemplary embodiment of the present invention. FIG. 3 (A) is a cross-section view of an entire SPR optical sensor according to the second exemplary embodiment of the present invention, and FIG. 3 (B) is a plan view of a semiconductor substrate of the SPR optical sensor according to the second exemplary embodiment of the present invention.

Referring to FIG. 3, in the second exemplary embodiment of the present invention, a light source 43, e.g., a laser diode, or light receivers 45a and 45b, e.g., photodiodes, are flip-chip bonded in the form of a chip as it is on a semiconductor substrate 47, such as a silicon substrate.

Using an optoelectronic device in the form of a chip, it is possible to further miniaturize the optical sensor, thus facilitating fabrication of an array of many sensors. However, a divergence angle of light emitted from the light source 43 is too large, and thus the light must be collimated into parallel light or substantially parallel light using a lens.

Therefore, in the second exemplary embodiment of the present invention, a divergence angle of light emitted from the light source 43 disposed on a lower surface of the semiconductor substrate 47 is controlled using lenses 41a and 41b in an optical path 10a to transmit the light to a diffraction grating plate 42.

As illustrated in FIG. 2, the diffraction grating plate 42 may move between the semiconductor substrate 47 and an optical glass substrate 48 to adjust a diffraction angle. However, the diffraction grating plate 42 may be fixed on the semiconductor substrate 47 without a movement device when it is unnecessary to adjust the diffraction angle.

However, light reflected from a sample stage 39 is passed through light receiving lenses 46a and 46b inserted and fixed into optical paths 10b and 10c formed in the semiconductor substrate 47 and polarizing plates 44a and 44b, and detected by the light receivers 45a and 45b.

The polarizing plates 44a and 44b are disposed at a position facilitating installation of the polarizing plates 44a and 44b in an optical path from the light source 43 to the light receivers 45a and 45b. However, when intensity of light emitted from the light source 43 is high, the polarizing plates 44a and 44b (particularly polymer thin films) may deteriorate, and thus it is better to avoid a position on which the light emitted from the light source 43 is focused.

Meanwhile, optical components used in the second exemplary embodiment of the present invention, that is, the sensor metal films 36a and 36b, the sample stage 39, the diffraction grating plate 42, the polarizing plates 44a and 44b, the semiconductor substrate 47, and the optical glass substrate 48 are the same as the optical components used in the first exemplary embodiment of the present invention. Thus, it is recommended to refer to the first exemplary embodiment of the present invention for detailed descriptions of the optical components.

### THIRD EXEMPLARY EMBODIMENT

FIG. 4 is a plan view and a cross-section view of an optical sensor using a laminated optical module according to a third exemplary embodiment of the present invention. FIG. 4 (A) is a cross-section view of an entire SPR optical sensor according to the third exemplary embodiment of the present invention, FIG. 4 (B) is a plan view of a silicon substrate of the SPR optical sensor according to the third exemplary embodiment of the present invention, and FIG. 4 (C) is an enlarged cross-section view of a diffraction grating 52 of FIG. 4 (A).

Referring to FIG. 4, in the third exemplary embodiment of the present invention, a light source 53, e.g., a laser diode, is separately fixed and disposed above a sample stage 39 other than a lower surface of a semiconductor substrate 57. Therefore, it is un-necessary to use an optical path, and the diffraction grating 52 is disposed on the semiconductor substrate 57.

As a semiconductor substrate for a diffraction grating, a silicon substrate having a [100] surface is used. Two surfaces of a groove of the diffraction grating 52 are formed by anisotropically etching silicon using a pattern of the diffraction grating 52 to have a [111] surface.

In other words, the diffraction grating 52 is formed so that a photosensitive film pattern line of the diffraction grating 52 is parallel with a line at which a [110] surface and a [100] surface cross each other. A photosensitive film pattern of the diffraction grating 52 is fabricated by a well-known hologram exposure method or electron beam exposure method used for manufacturing a Distributed Feedback (DFB) laser diode.

Here, a cross-section of the groove of the diffraction grating 52 is, for example, an isosceles triangle, and the [111] grating surface and a [100] substrate surface form an angle of about 50 to 60 degrees (preferably about 54.7 degrees). The substrate surface, that is, the [100] surface, is left between grating grooves by a residual photosensitive film pattern. Thus, it is preferable to minimize the residual of the [100] surface by minimal isotropic etching or undercutting. When silicon etching is finished, a reflective metal film is deposited on the etched silicon to complete a reflective diffraction grating.

It is described above that the angle between the grating surface and the substrate surface may be 54.7 degrees. When the angle is 54 degrees, incident light perpendicular to the substrate surface is reflected twice by surfaces 52a and 52b and then travels in a direction exactly parallel with the surface 52a or 52b.

This is similar to a blazing angle frequently used in a general reflective diffraction grating. However, while light is reflected only once to be diffracted according to diffraction by the general blazing angle, light is reflected twice and then diffracted according to the third exemplary embodiment of the present invention.

Such a structure has an advantage in that efficiency of +1-th order diffraction and-1-th order diffraction can be maximized while angles of +I-th order diffraction and −1-th order diffraction are about 45 degrees or more. However, while one of +I-th order diffraction and −1-th order diffraction can be achieved according to diffraction by a general blazing angle, only symmetrical diffraction of +I-th order diffraction and −1-th order diffraction occurs according to diffraction using a diffraction grating fabricated by anisotropically etching silicon.

In the third exemplary embodiment of the present invention, the light receivers 55a and 55b, e.g., photodiodes, are fabricated on the semiconductor substrate 57, e.g., a silicon substrate.

An emission angle of light reflected from the sample stage 39 is about 45 degrees or more, and a reflectance at a surface of the semiconductor substrate 57 is high. Thus, an absorptance at the light receivers 55a and 55b fabricated on the semiconductor substrate 57 significantly deteriorates.

Therefore, it is necessary to anisotropically etch the upper surface of the semiconductor substrate to form the grating patterns 55a and 55b and thereby reduce reflection of light.

When a silicon substrate surface is a [100] surface, an angle between the substrate surface and an etched surface is about 54.7 degrees after anisotropic etching. Here, reflection from the light receivers 55a and 55b fabricated on the silicon substrate surface is minimized as described with reference to the diffraction grating 52.

In the third exemplary embodiment of the present invention, polarization of light emitted from the light source 53 is controlled by a diode module or a chip instead of a polarizing plate, so that only TM light is incident on metal sensor films 36a and 36b without using a polarizing plate.

Meanwhile, optical components used in the third exemplary embodiment of the present invention, that is, the sensor metal films 36a and 36b, the sample stage 39, an optical glass substrate 48 and the semiconductor substrate 57 are the same as the optical components used in the first exemplary embodiment of the present invention. Thus, it is recommended to refer to the first exemplary embodiment of the present invention for detailed descriptions of the optical components.

### FOURTH EXEMPLARY EMBODIMENT

FIG. 5 is a plan view and a cross-section view of an optical sensor using a laminated optical module according to a fourth exemplary embodiment of the present invention. FIG. 5 (A) is a cross-section view of an entire SPR optical sensor according to the fourth exemplary embodiment of the present invention, and FIG. 5 (B) is a plan view of a sample stage and an optical glass substrate of the SPR optical sensor according to the fourth exemplary embodiment of the present invention.

Referring to FIG. 5, an SPR angle exceeds critical angles of most optical glasses. Therefore, signal light may be led to a side of a sample stage 39 or an optical glass substrate 48 by total internal reflection at the sample stage 39 or the optical glass substrate 48.

In the fourth exemplary embodiment of the present invention, photodetectors, that is, light receivers 65a and 65b are not disposed on a lower surface of a semiconductor substrate 67, and light is totally reflected and detected at sides of the optical sensor.

Light emitted from a light source 43, such as a laser diode having a form of a chip, is passed through lenses 41a and 41b in an optical path 10 and diffracted by a diffraction grating plate 62 to sensor metal films 36a and 36b.

Here, a period of the diffraction grating plate 62 intermittently changes like that of the first exemplary embodiment of the present invention.

The light sensed by SPR of the sensor metal films 36a and 36b travels in the sample stage 39 and the optical glass substrate 48 while being totally reflected. Then, the light is passed through polarizing plates 64a and 64b at edges of the sensor and detected by the light receivers 65a and 65b, such as photodiodes.

Meanwhile, optical components used in the fourth exemplary embodiment of the present invention, that is, the sensor metal films 36a and 36b, the sample stage 39, the diffraction grating plate 62, the polarizing plates 64a and 64b, the semiconductor substrate 67, the optical glass substrate 48 and the light receivers 65a and 65b, are the same as the optical components used in the second exemplary embodiment of the present invention. Thus, it is recommended to refer to the second exemplary embodiment of the present invention for detailed descriptions of the optical components.

While the invention has been shown and described with reference to certain exemplary embodiments of an optical module, an optical sensor using the optical module, and a method of manufacturing the optical module, it will be understood by those skilled in the art that various changes in form and details may be made therein without departing from the spirit and scope of the invention as defined by the appended claims.

1. An optical module, comprising:
a substrate having at least one optical path; and
at least one lens inserted and fixed into the optical path to refract incident light.

2. The optical module of claim 1, wherein the optical path is formed in the shape of a pyramidal hole perpendicularly penetrating the substrate so that an upper surface and a lower surface of the substrate can be optically connected.

3. The optical module of claim 1, wherein the lens has a spherical shape, and a part of the lens projected on the substrate is evenly ground when the lens is inserted into the optical path.

4. The optical module of claim 3, further comprising: a light source for generating light on a substrate surface around the optical path or the evenly ground lens; or a photodetector for detecting incident light.

5. (canceled)

6. An optical module, comprising: a substrate having at least one optical path having a transparent optical medium of a predetermined thickness; and an optical component formed on the transparent optical medium to perform an optical function.

7. The optical module of claim 6, wherein the transparent optical medium comprises a silicon oxide glass film.

8. The optical module of claim 6, wherein the optical path is formed in the shape of a pyramidal groove formed on one surface or both surfaces of the substrate, and the transparent optical medium of a predetermined thickness is formed on an inner surface of the groove so that an upper surface and a lower surface of the substrate can be optically connected.

9-11. (canceled)

12. An optical sensor, comprising: a semiconductor substrate having a plurality of optical paths;
an optical glass substrate formed on the semiconductor substrate;
a sample stage formed on the optical glass substrate;
at least one sensor metal film formed on the sample stage, and sensing light by Surface Plasmon Resonance (SPR) to reflect the light at a predetermined angle;
a light source disposed on a lower surface of the semiconductor substrate, and emitting light having a specific wavelength toward one of the optical paths;
a polarizing plate disposed between the semiconductor substrate and the light source, and polarizing the light emitted from the light source into transverse-magnetic light;
a diffraction grating plate disposed between the semiconductor substrate and the optical glass substrate, and diffracting the polarized light at a specific angle to be incident on the sensor metal film; and
at least one light receiver disposed on the lower surface of the semiconductor substrate, and detecting the light passed through at least one of the optical paths and reflected from the sensor metal film.

13. (canceled)

14. The optical sensor of claim 12, wherein the diffraction grating plate is installed to move along a guide groove formed on the semiconductor substrate in order to adjust the diffraction angle.

15. The optical sensor of claim 14, further comprising:
an optical fluid for lubrication for making the diffraction grating plate smoothly move along the guide groove.

16. (canceled)

17. An optical sensor, comprising: a semiconductor substrate having a plurality of optical paths;
an optical glass substrate formed on the semiconductor substrate;
a sample stage formed on the optical glass substrate;
at least one sensor metal film formed on the sample stage, and sensing light by Surface Plasmon Resonance (SPR) to reflect the light at a predetermined angle;
a light source disposed on a lower surface of the semiconductor substrate, and emitting light having a specific wavelength toward one of the optical paths;
at least one lens inserted and fixed into the optical paths to refract the light emitted from the light source;
a diffraction grating plate disposed between the semiconductor substrate and the optical glass substrate, and diffracting the light refracted by the lens at a specific angle to be incident on the sensor metal film;
at least one light receiver disposed on the lower surface of the semiconductor substrate, and detecting the light passed through at least one of the optical paths and reflected from the sensor metal film; and
a polarizing plate disposed between the semiconductor substrate and the light receiver, and polarizing the light reflected from the sensor metal film into transverse-magnetic light.

18. (canceled)

19. An optical sensor, comprising:
a semiconductor substrate having at least one optical path;
an optical glass substrate formed on the semiconductor substrate;
a sample stage formed on the optical glass substrate;
at least one sensor metal film formed on the sample stage, and sensing light by Surface Plasmon Resonance (SPR) to reflect the light at a predetermined angle;
a light source disposed on a lower surface of the semiconductor substrate, and emitting light having a specific wavelength toward the optical path;
at least one lens inserted and fixed into the optical path to refract the light emitted from the light source;
a diffraction grating plate disposed between the semiconductor substrate and the optical glass substrate, and diffracting the light refracted by the lens at a specific angle to be incident on the sensor metal film;
at least one light receiver disposed on a side of the semiconductor substrate, and detecting the light reflected from the sensor metal film and totally reflected by the optical glass substrate and the sample stage; and
a polarizing plate disposed between the side of the semiconductor substrate and the light receiver, and polarizing the light reflected from the sensor metal film into transverse-magnetic light.

20-24. (canceled)

25. The optical sensor of claim 12, further comprising: a protective glass of a predetermined thickness formed on a diffractive surface to prevent a diffraction grating of the diffraction grating plate from being optically contaminated.

26. The optical sensor of claim 12, wherein the diffraction grating plate prevents 0-th order diffraction and diffracts light in symmetric directions for +I-th and −1-th order diffraction using a sectional structure of a diffraction grating line enhancing +−I-th order diffraction, and is constituted to continuously or intermittently change a period of a grating.

27. The optical sensor of claim 26, wherein the symmetrically disposed two light receivers each detect light reflected from the symmetrically disposed two sensor metal films, and signals of the two light receivers are differentially amplified using light detected by one of the sensor metal films as reference light and light detected by the other sensor metal film as measurement light.

28. (canceled)

29. An optical sensor, comprising:
a semiconductor substrate; an optical glass substrate formed on the semiconductor substrate; a sample stage formed on the optical glass substrate;
at least one sensor metal film formed on the sample stage, and sensing light by Surface Plasmon Resonance (SPR) to reflect the light at a predetermined angle;
a light source disposed on the sample stage, and emitting light having a specific wavelength toward an upper surface of the semiconductor substrate;
a plurality of diffraction gratings formed on the upper surface of the semiconductor substrate, and diffracting the light emitted from the light source at a specific angle to be incident on the sensor metal film; and
at least one light receiver formed on the upper surface of the semiconductor substrate at a specific distance from the diffraction gratings, and detecting the light reflected from the sensor metal film.

30. The optical sensor of claim 29, wherein the semiconductor substrate is a silicon substrate having a [100] surface, and two surfaces of a groove of the diffraction gratings are formed by anisotropically etching silicon using a pattern of the diffraction gratings to have a [111] surface.

31. (canceled)

32. The optical sensor of claim 29, wherein diffraction of the diffraction gratings is symmetric diffraction of +I-th order and −1-th order performed by twice reflecting the light emitted from the light source and perpendicularly incident on the substrate.

33. The optical sensor of claim 29, wherein the light receiver is a photodiode, and a grating pattern is formed in the semiconductor substrate on the photodiode to reduce reflection of the light transmitted from the sensor metal film.

34. (canceled)

35. A method of manufacturing an optical module, comprising the steps of: (a) preparing a substrate having a predetermined thickness; (b) forming at least one optical path in the substrate; and (c) inserting and fixing at least one lens for refracting light incident into the optical path.

36. The method of claim 35, wherein when the substrate is a silicon substrate, the optical path is formed in the shape of a pyramidal hole perpendicularly penetrating the silicon substrate by anisotropically etching the silicon substrate using a specific pattern.

37. The method of claim 35, wherein when the substrate is a silicon substrate having a [100] surface, step (b) comprises the steps of:
(b-1) forming a silicon nitride film or a silicon oxide film on at least one of an upper surface and a lower surface of the silicon substrate;
(b-2) forming a rectangular photosensitive film pattern on the silicon nitride film or silicon oxide film using a planographic printing process;
(b-3) transfer-etching the photosensitive film pattern to transfer the pattern on the silicon nitride film or silicon oxide film; and
(b-4) anisotropically etching the silicon substrate using the pattern transferred on the silicon nitride film or silicon oxide film as an etch mask to form the optical path having a pyramidal hole.

38-39. (canceled)

40. A method of manufacturing an optical module, comprising the steps of:
(a') preparing a substrate having a predetermined thickness;
(b') forming at least one optical path having a transparent optical medium on the substrate; and
(c') forming an optical component for performing various optical functions on the transparent optical medium.

41. The method of claim 40, wherein when the substrate is a silicon substrate having a [100] surface, the transparent optical medium is formed by oxidizing a part of the silicon substrate.

42. The method of claim 40, wherein when the substrate is a silicon substrate, step (b') comprises the steps of:
(b'-I) forming an optical path pattern on at least one of an upper surface and a lower surface of the silicon substrate using a planographic printing process; and
(b'-2) anisotropically etching the silicon substrate to leave a silicon film having a predetermined thickness, and then oxidizing the silicon film to convert the silicon film into a transparent optical medium having a silicon oxide glass film and thereby form the optical path.

43-46. (canceled)
